(19) United States
(12) Patent Application Publication
(10) Pub. No.: US 2019/0241785 A1
(43) Pub. Date: Aug. 8, 2019

(54) MOLECULAR ENGINEERED CONJUGATED POLYMER WITH HIGH THERMAL CONDUCTIVITY

(71) Applicant: Massachusetts Institute of Technology, Cambridge, MA (US)

(72) Inventors: Gang Chen, Carlisle, MA (US); Karen K. Gleason, Cambridge, MA (US); Yanfei Xu, Cambridge, MA (US); Xiaoxue Wang, Cambridge, MA (US)

(21) Appl. No.: 16/250,717

(22) Filed: Jan. 17, 2019

Related U.S. Application Data
(60) Provisional application No. 62/619,212, filed on Jan. 19, 2018.

(51) Int. Cl. C09K 5/14; C08G 61/12; C09D 165/00; H01L 21/02

(52) U.S. Cl. CPC C09K 5/14; C08G 61/126; C09D 165/00; H01L 21/02118; C08G 2261/43; C08G 2261/11; C08G 2261/1414; C08G 2261/334; H01L 21/02271

(57) ABSTRACT

Disclosed are thermally conductive quinoid-type conjugated polymer thin films. One such film comprises conjugated poly(3-hexylthiophene) (P3HT). The thin films can be fabricated using oxidative chemical vapor deposition (oCVD), which offers unique advantages for integrating polymer films into various devices. By avoiding the use of solvents in the deposition of monomers and oxidants and undesirable solvent-derived surface-tension driven effects, such as dewetting, the oCVD coatings can conformally coat complex geometries, can be scaled to large areas, and can be fabricated at relatively low substrate temperatures on electrically insulating substrates. Disclosed is the formation of ordered polymer structures with rigid backbones achieved by oCVD with stacking in the transverse direction via π-π interactions. P3HT films with record-high thermal conductivity of 2.2 W/m-K near room temperature have been prepared.

### CROSS REFERENCE TO RELATED APPLICATION

This application claims the benefit of priority to U.S. Provisional Application No. 62/619,212, filed Jan. 19, 2018.

### GOVERNMENT SUPPORT

This invention was made with Government support under Grant No. DE-FG02-02ER45977 awarded by the Department of Energy. The Government has certain rights in the invention.

### BACKGROUND

Polymers have infiltrated almost every aspect of modern technology¹. Wearable sensors, soft robotics, and 3D printing are all examples of advanced technologies enabled by flexible and lightweight polymers¹. However, polymers are still primarily regarded as heat insulators^{2,3}, and low thermal conductivity (˜0.2 W/m-K) has hindered their adoption in a variety of applications. Until now, metals and ceramics remain the dominant heat conductors.

The low thermal conductivity of polymers is generally considered a result of structural disorders and weak molecular interactions^{2,3}. By systematically improving the alignment of molecular chains through stretching⁴⁻⁹, template-assisted technique^{10,11}, or surface-grafted method₁₂, etc., polymers with orders-of-magnitude higher thermal conductivities along the chain direction have been reported^{4-9,10,11}. More specifically, a thermal conductivity ˜104 W/m-K has been reported for ultradrawn polyethylene nanofiber⁷; and a thermal conductivity ˜4.4 W/m-K has been achieved in polythiophene nanofibers¹⁰ obtained by the nanoscale template-assisted electropolymerization. Thermal conductivities of greater than ˜2 W/m-K have been reported for surface-grafted polymer brushes¹². However, these approaches either pose scalability challenges for practical applications, or are limited to the anisotropic scenario of high thermal conductivity along the chain direction and low thermal conductivity between the chains¹³. The problem of poor interchain thermal transport is due to the weak van der Waals (vdW) force between the chains³. Recently, intermolecular hydrogen bonding has been exploited as a means to go beyond vdW interactions¹⁴⁻¹⁶, leading to a significantly increased isotropic thermal conductivity of ˜1.5 W/m-K¹⁵. Alternatively, thermal conductivity has also been increased to ˜1.2 W/m-K by electrostatically engineered amorphous polymers¹⁷. However, these approaches either require specific pH environment or pose challenges in terms of stability and reliability for practical applications¹⁴. To date, it remains a long-standing challenge to enhance the thermal conductivity of polymers by simultaneously engineering the intramolecular and intermolecular interactions, which is the key to realizing high isotropic thermal transport.

Conjugated polymers are potential candidates for good thermal conductors, as a result of the rigid conjugated backbone and the strong intermolecular π-π stacking interactions. Whereas the carbon-carbon single bonds (C—C, ˜347 kJ/mole)¹⁸ are prevalent in diamond and stretched polyethylene which have shown ultrahigh thermal conductivities (˜2000 W/m-K for diamond¹⁹ and ˜100 W/m-K for stretched polyethylene⁷), the conjugated double bonds (C═C, ˜610 kJ/mole) are nearly twice as strong, and thus are expected to dramatically improve phonon transport along the polymer chains²⁰. Furthermore, π-π stacking interaction between the chains is approximately 10-100 times stronger than vdW interactions (weak vdW ˜0.4-4 kJ/mole)²¹, which could substantially enhance phonon transport across the chains. However, traditional conjugated polymers are characterized by low thermal conductivities (˜0.2 W/m-K) similar to non-conjugated polymers. Researchers hypothesize that such low thermal conductivity is due to strong phonon scatterings by chain distortions and entanglements, etc^{3,20}. To realize the full potential of conjugated polymers, the critical challenge that remains is how to precisely control the conformation of the planar conjugated backbones together with the interchain π-π packing at the molecular level.

### SUMMARY

The present disclosure describes thermally conductive quinoid-type conjhugated polymer thin films. In one conjugated poly(3-hexylthiophene) (P3HT) thin film fabricated using oxidative chemical vapor deposition (oCVD). This all-dry vapor-phase technique synthesizes monomers directly into polymeric thin film via step growth polymerization. An oCVD approach as described herein offers unique advantages for integrating polymer films into various devices.²³ By avoiding the use of solvents in the deposition of monomers and oxidants and undesirable solvent-derived surface-tension driven effects such as dewetting, the oCVD coatings can conformally coat complex geometries. Moreover, oCVD methods can be scalable to large areas and can be carried out at relatively low substrate temperatures on electrically insulating substrates. This can allow virtually any surface to be coated. The present disclosure describes the formation of ordered polymer structures with rigid backbones achieved by oCVD with stacking in the transverse direction via π-π interactions. By simultaneously harnessing the strong conjugated bonds along polymer chains and the π-π interactions between them, as demonstrated herein, it is possible to obtain a record-high thermal conductivity of 2.2 W/m-K near room temperature in P3HT films.

Accordingly, in one embodiment, the present disclosure provides a thin film comprising a plurality of polymer chains, wherein each polymer chain is a polymer of at least one monomer; each polymer chain comprises a quinoid-type region, wherein the quinoid-type region comprises an extended array of conjugated n-bonds, and said quinoid-type region has a rigid, planar molecular configuration; said quinoid-type regions of the polymer chains interact electronically; said thin film comprises at least one area wherein said polymer chains are well-ordered; and said thin film exhibits a thermal conductivity (κ) of at least about 1 W/mK at 23° C.

In some embodiments, the at least one monomer is an unsubstituted or substituted quinone, pyridine, pyridone, pyrimidine, pyrimidone, thiophene, thiophenone, pyrrole, furan, or a combination of any of them. In some embodiments, the unsubstituted or substituted quinone, pyridine, pyridone, pyrimidine, pyrimidone, thiophene, thiophenone, pyrrole, furan, or combination thereof has been oxidized. In certain embodiments, the at least one monomer is an alkylthiophene. In certain embodiments, the alkylthiophene is a 3-alkylythiophene. In one embodiment, the 3-alkylthiophene is 3-hexylthiophene.

In some embodiments, the thin film exhibits a thermal conductivity of at least about 1.5 W/mK at 23° C. In some embodiments, the thin film exhibits a thermal conductivity of at least about 2 W/mK at 23° C. In certain embodiments, the thin film exhibits a thermal conductivity (κ) of at least about 2.1 W/mK at 23° C. In some embodiments, the thin film has at least one area that exhibits polycrystalline characteristics. In some embodiments, the polycrystalline characteristics are visible by x-ray scattering. In certain embodiments, electronic interactions as described can comprise comprise π π-interactions.

In some embodiments, the thin film has a thickness of about 5 nm to about 100 μm. In some embodiments, the polymer chains are homopolymers. In other embodiments, the polymers chains are heteropolymers. In certain embodiments, the thin further comprises an oxidant. In some embodiments, the oxidant is a metal halide. In some embodiments, the metal halide is FeCl₃. In some embodiments, the thin film is in contact with a surface of a substrate. In certain embodiments, the present disclosure also provides a semiconductor device comprising a thin film as described herein. In certain embodiments, the present disclosure also provides a consumer electronics device comprising a thin film as described herein.

In still other embodiments, the present disclosure provides a method of preparing a thin film on a surface of a substrate, comprising the steps of depositing at least one monomer on said surface, thereby forming a coated surface; depositing an oxidant on said coated surface; and allowing said at least one monomer and said oxidant to react, thereby forming said thin film on said surface of said substrate. In some embodiments, the method includes forming the thin film on a substrate wherein the substrate is a semiconductor device. In other embodiments, the method includes forming the thin film on a substrate wherein the substrate is a consumer electronics device.

### BRIEF DESCRIPTION OF THE FIGURES

FIG. 1A shows (left) growth process of exemplary thin films via oCVD with monomer (3-hexylthiophene) and oxidant (FeCl₃); (middle) schematic presentation of the microstructure of a doped P3HT film; and (right) extended chain of an exemplary polymer having a quinoid structure grown with FeCl₃.

FIG. 1B shows (left) exemplary P3HT thin film and methanol rinsing to dissolve the excess oxidant and dedope (reduce) the polymer; (middle) schematic presentation of the microstructure of a dedoped P3HT film; and (right) an exemplary polymer with the rotatable single bond.

FIG. 1C shows Atomic Force Microscopy (AFM) image of 45° C.-grown P3HT/FeCl₃ with 40 min polymerization time.

FIG. 1D shows AFM image of 85° C.-grown P3HT/FeCl₃ with 40 min polymerization time.

FIG. 1E is an AFM image of de-doped 45° C.-grown P3HT.

FIG. 1F is an AFM image of dedoped 85° C.-grown P3HT.

FIG. 2 is a chart displaying measured thermal conductivity of an exemplary P3HT/FeCl₃ thin film using time-domain thermoreflectance.

FIG. 3A is a UV-vis-Near-IR spectrum of 45° C. and 85° C.-grown P3HT/FeCl₃ films.

FIG. 3B is a UV-vis-Near-IR absorption spectra of 45° C. and 85° C.-grown P3HT/FeCl₃ films.

FIG. 4A shows grazing incidence wide angle X-ray scattering (GIWAXS) pattern of 45° C.-grown P3HT.

FIG. 4B shows GIWAXS patterns of 85° C.-grown P3HT suggest the amorphous phase is dominant.

FIG. 5 is a schematic presentation of an oCVD reactor for the manufacturing thermally conductive P3HT thin films as described herein.

FIG. 6A shows the chemical structure of an exemplary monomer 3-hexylthiophene for making thin films as described herein.

FIG. 6B depicts an exemplary step-growth polymerization process: (1) oxidation of 3HT to from cation radical; (2) dimerization of cation radical; (3) deprotonation to form conjugation; (4) step growth polymerization process; (5) simultaneous chlorine doping of polymer backbone; and (6) dedoping of polymer backbone by methanol.

FIG. 6C shows possible regiochemical coupling configurations in P3HT.

FIG. 6D depicts Exemplary quinoid and aromatic structures.

FIG. 7A is a cartoon depicting random coils and entanglements in typical polymer chains.

FIG. 7B is a cartoon depicting the extended and less entangled polymer chain of 45° C.-grown P3HT with π-π stacking regions.

FIG. 8 is AFM images of P3HT/FeCl₃ films—left image—nanorod-like 45° C.-grown P3HT/FeCl₃, 10 minute's oxidative coupling polymerization;—right image—85° C.-grown P3HT/FeCl₃, 10 minute's oxidative coupling polymerization.

FIG. 9 is graphs showing erlemental analysis by energy dispersive X-ray spectroscopy of 45° C. and 85° C.-grown P3HT which demonstrate the signature elements (S and C) of P3HT and no residue left on the P3HT after the dedoping process.

FIG. 10A depicts structural characterization of the present thin films using synchrotron X-ray scattering—illustration of the grazing incidence wide angle X-ray scattering setup (GIWAXS)

FIG. 10B depicts a structural characterization of the present thin films using synchrotron X-ray scattering—illustration of schematic P3HT crystal packing.

FIG. 11A shows NMR spectra of the present films—45° C.-grown P3HT, ¹H NMR (CDCl³): δ 0.50-1.00 (3H, —CH₃), 1.00-2.00 (8H, —(CH₂)₄—), 2.33-3.00 (2H, ring-CH₂ from both HT coupling and non-HT-coupling). 6.60-7.16 (1H, ring proton). The ratio of regioregular to regiorandom couplings is 3:2, which is estimated by the relative integration of the HT couplings (δ=2.79 ppm) and non-HT couplings (δ=2.56 ppm)⁴⁰

FIG. 11B shows NMR spectra of the present films-85° C.-grown P3HT, ¹H NMR (CDCl₃): δ 2.36-2.90 (2H, ring-CH₂from HT and non-HT-coupling coupling), 6.92-7.12 (1H, ring proton). The ratio of regioregular to regiorandom couplings is 1:1, which is estimated by the relative integration of the HT couplings (δ=2.79 ppm) and non-HT couplings (δ=2.55 ppm). Samples are dissolved in deuterated chloroform (CDCl₃), and the NMR chemical shifts (δ) are reported in ppm with reference to residual protons of CDCl₃ (δ7.26 ppm in ¹H NMR).

FIG. 12 is a graph reporting specific heat results for 45° C. and 85° C.-grown P3HT.

FIG. 13A depicts Raman spectra of 45° C. and 85° C.-grown P3HT. The band at ˜1450 cm⁻¹ is Cα=Cβ³³ bond in the aromatic thiophene ring, and it is associated with neutral conjugated polythiophene segments; the weak shoulder at ˜1375 cm⁻¹ is assigned to the Cβ-Cβ′ vibration in the thiophene ring; the band at ˜1222 cm⁻¹ is assigned to the vibration of the Cα-Cα′ linkage between adjacent thiophene rings; and ˜740 cm⁻¹ is assigned to ring deformation

FIG. 13B shows the ordered phase with respect to its disordered phase is identified by a narrower full width at half maximum of the Cα=Cβ mode. A shift of the C_{α}=C_{β} band toward lower wavenumber indicates a higher conjugation length, which agrees with the conjugation length from UV/Vis results.

FIG. 14 is a schematic presentation of a femtosecond pulsed laser-based setup employed for thermal conductivity measurement using time-domain thermoreflectance.

FIG. 15A is a graph showing measured and fitted thermoreflectance signals—phase signal.

FIG. 15B depicts normalized amplitude signal for the same measurement. The best fit for the thermal conductivity agrees well with the phase as well as amplitude signal across the delay time, while a different guess for the thermal conductivity leads to significant deviation from the measurement curve.

### DETAILED DESCRIPTION

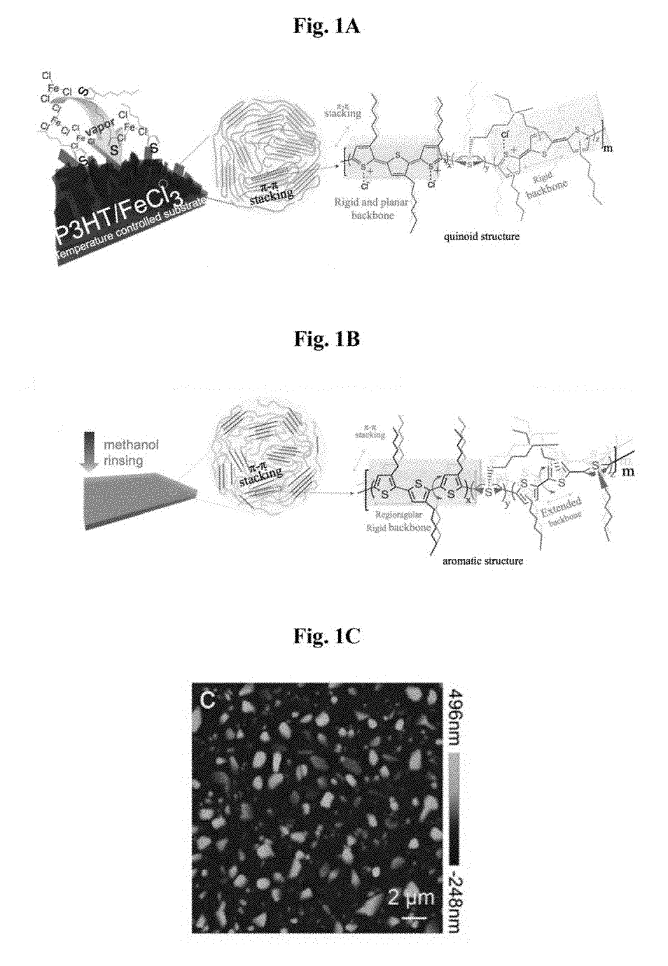

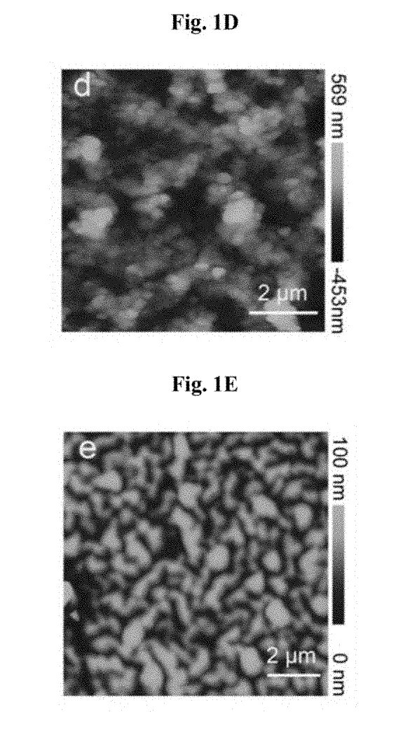

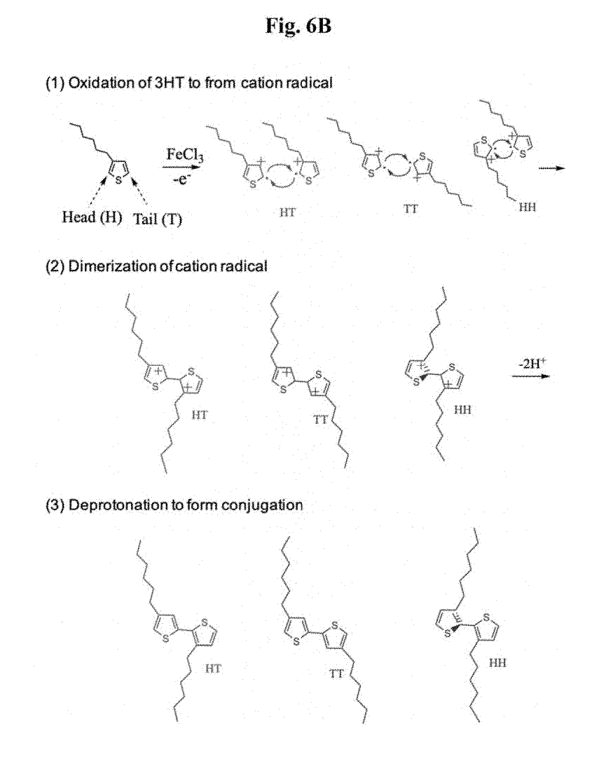

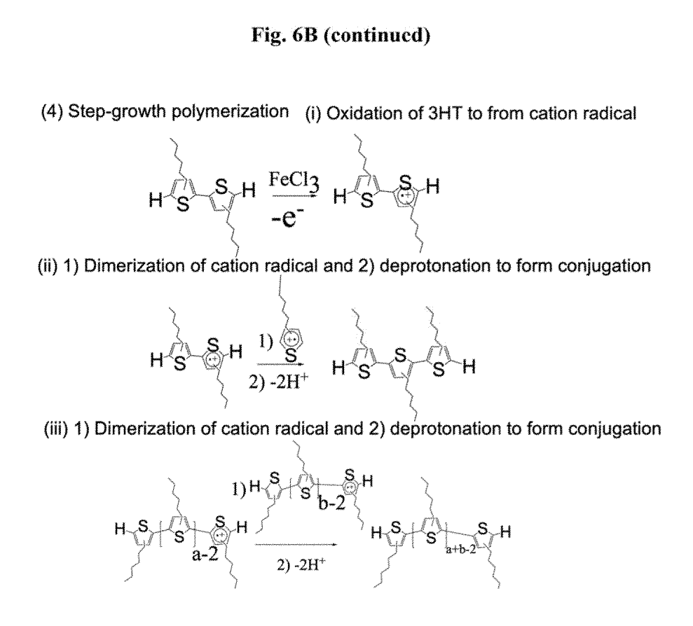

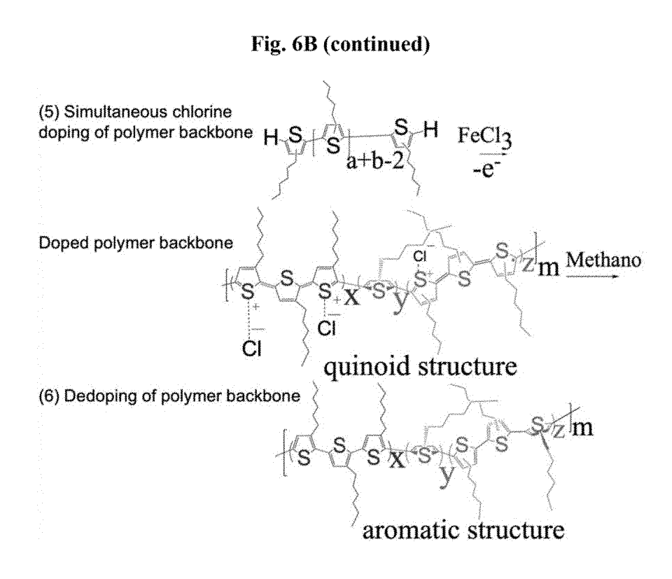

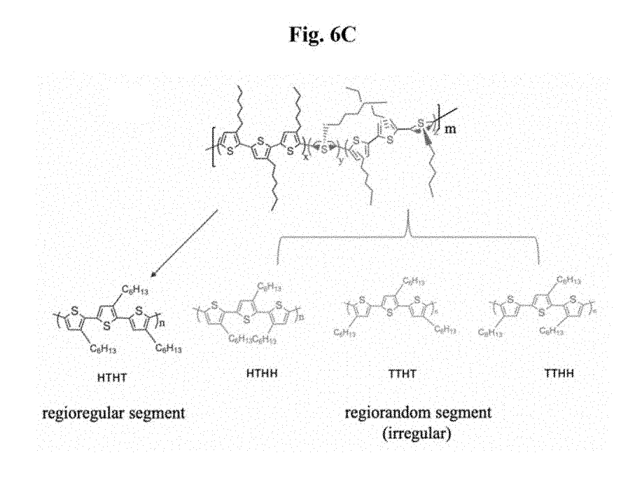

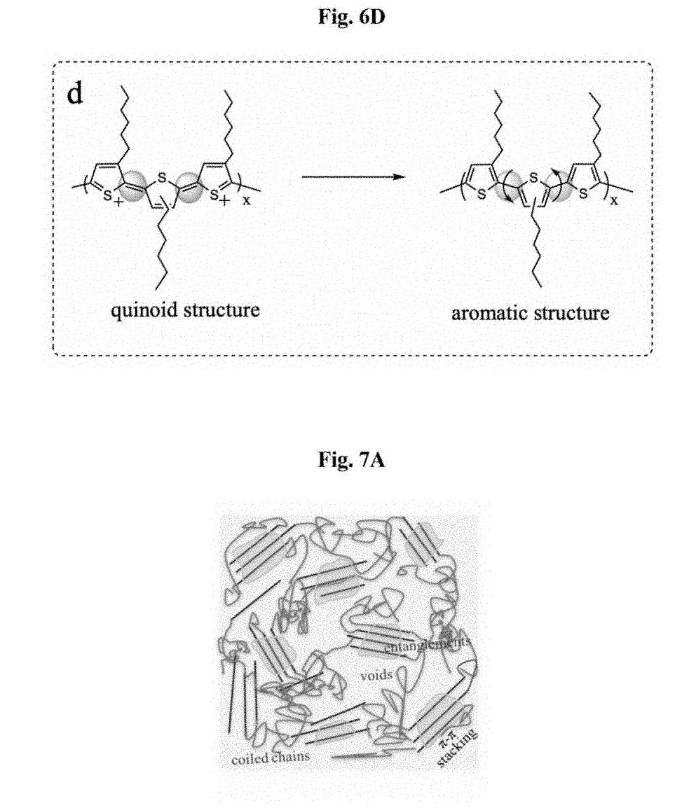

In one aspect, the present disclosure relates to polymer thin films having high thermal conductivities. In one aspect, such polymer thin films can be formed by oxidative chemical vapor deposition (oCVD). FIGS. 1A-1D depict one embodiment of the contemplated design concept and synthesis strategy for polymer thin films as described herein. FIG. 1A (left) depicts one embodiment of the growth process of exemplary P3HT/FeCl₃ thin films which includes the initialization of the film growth with adsorbed monomer (3-hexylthiophene) and oxidant (FeCl₃) from the vapor phase and continuous growth of “nanorod-like” structures. FIG. 1A (middle) depicts a microstructure of a doped P3HT film, wherein ordered chain grains (darker shadowed areas) arise from π-π stacking assemblies, and disordered chain grains have rigid backbones with suppressed distortions. FIG. 1A (middle) depicts an embodiment wherein the extended chain of quinoid subunits grown with a FeCl₃ oxidant. In some embodiments, both polarons and bipolarons are present in the doped P3HT backbone. In certain embodiments, during the chain growth process by oCVD, π-π stacking and rigid backbone are simultaneously achieved, as depicted in FIGS. 6A-6D.

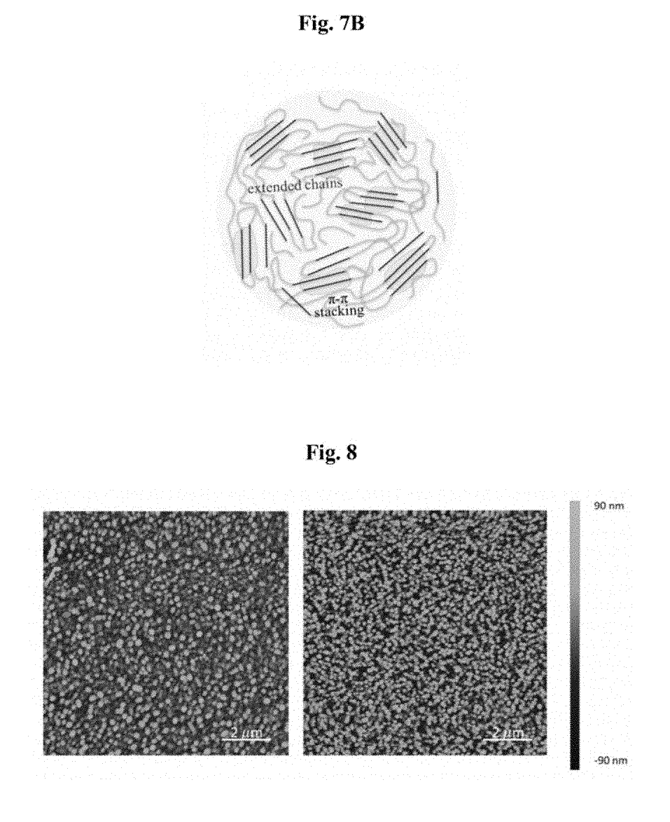

FIG. 1B (left) depicts an exemplary P3HT thin film. As shown, in one embodiment the method of making the present thin films includes a methanol rinsing step to dissolve excess oxidant. In some embodiments, methanol rinsing can also dedpope or reduce the polymer backbone. FIG. 1B (left) depicts one embodiment where the microstructure of a dedoped P3HT film exhibits ordered chain grains (darker shadowed areas) from π-π stacking assemblies, and extended chains with suppressed distortions, which originate from the quinoid structures depicted in FIG. 1A. Unlike coiled and entangled chains in common polymers (see, e.g., FIG. 7A), the extended chain of the dedoped P3HT is shown in right side. FIGS. 1C-1F depict exemplary film morphologies characterized by tapping-mode AFM: (1C) 45° C.-grown P3HT/FeCl₃ (40 min-polymerization) (1D) 85° C.-grown P3HT/FeCl₃ (40 min-polymerization). (1E) De-doped 45° C.-grown P3HT. (1F) Dedoped 85 ° C.-grown P3HT.

In one embodiment, the oCVD process includes introduction of vaporized monomers and oxidants in a vacuum chamber. In some embodiments, the monomers are aromatic monomers. In some embodiments, the monomer is 3-hexylethiophene. In some embodiments, the oxidant ais a metal complex. In one embodiment, the metal oxidant is iron trichloride (FeCl₃). In one embodiment, the oCVD process includes physical adsorption of monomers and oxidants onto a substrate. In some embodiments, the substrate is cooled. In other embodiments, the substrate has a temperature of from 0° C. to 8° C. In one embodiment, the substrate temperature is from 0° C. to 23° C. In one embodiment, the substrate is at a temperature of 45° C. In one embodiment, the substrate is at 85° C. In one embodiment, the oCVD process includes step-growth of a polymer on the substrate by oxidative coupling polymerization of adsorbed monomers.

oCVD-grown polymer films generally have high chemical purity with no residues as compared to solution based processes because the vapor deposition process is inherently free of solvents and additives²³⁻²⁵. As described herein, exemplary P3HT thin films can be grown at two or more different substrate temperatures (e.g., 45° C. and 85° C)²³. In some emmbodiments, the adsorption of monomer (e.g., 3-hexylthiophene) and oxidant (FeCl₃) onto the surface can limit the polymerization rate. Moreover, low substrate temperatures can promote adsorption and lead to rapid polymerization²⁶.

In some embodiments, oxidants on the substrate also serve as hosting templates for the polymer chains growing on the substrate surfaces. In some embodiments, excessive oxidants can heavily oxidatively dope the polymer backbone during the chain growth process, significantly stabilizing the quinoid structure of the resultant polymer with a conjugated segment with rigid double bonds linking two thiophene rings (FIG. 1A (right)) instead of the rotatable single bond (FIG. 1B (right))—at the molecular level (FIG. 1 and FIG. 6D). The presence of a quinoid structure in the polymer, as confirmed by ultraviolet-visible-near-infrared spectroscopy (UV-vis-NIR), can be important for obtaining high thermal conductivity because of their high planarity arising from double bonds and extended conjugation²⁶. Such planarity can enable regular self-assembly of multiple polymer chains through π-π stacking force (FIGS. 1A and 1B).

Thus, in some embodiments P3HT with a rigid, planar conjugated backbone and strong interchain π-π interactions can be obtained simultaneously during the polymerization process (FIGS. 1A-1B)²⁷. In some embodiments, the thin film is rinsed with methanol after formation on the substrate. After a methanol rinsing process, the polymer backbone can be reduced (dedoped), and an extended aromatic chain of the polymer can be obtained, in contrast with the usual coiled and entangled chains in polymers (FIG. 1B, FIG. 6B and FIG. 7A-B).

In some embodiments, the substrate can be silicon, metal, plastic, an oxide, a ceramic, or any other substrate suitable for the formation of such thin films or useful in the construction of devices comprising such thin films. Thus, in some embodiments, the present thin films mat be employed in semiconductor devices such as transistors, diodes, or other microelectronic structures. In some embodiments, the present thin films may be employed in electronics devices such as consumer electronics. In some embodiments, the consumer electronics include tablets, smartphones, displays, etc.

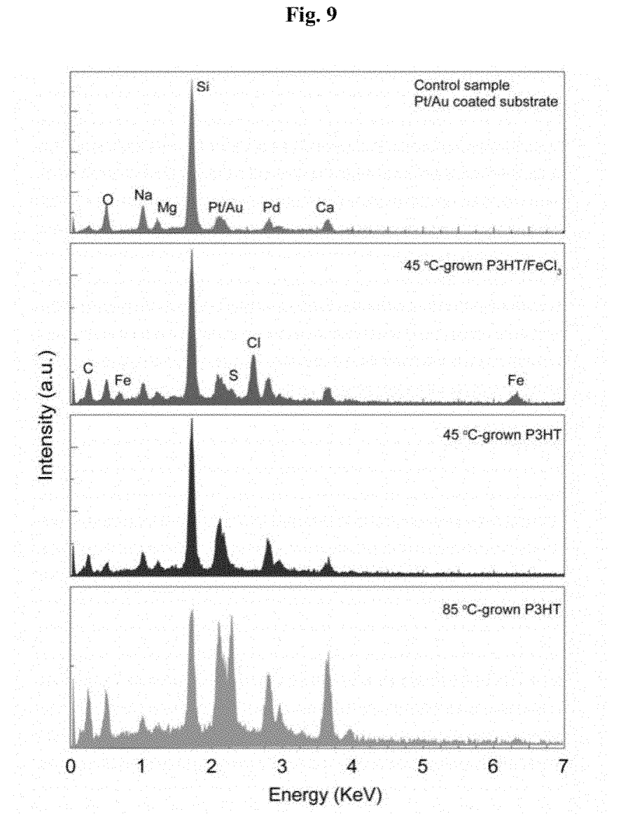

Atomic force microscopy (AFM) reveals the unique nanorod-like growth mechanism of oCVD. After only 10 minutes of deposition, island growth is observed, with the 45° C.-grown P3HT/FeCl₃ condition resulting in larger islands than in 85° C.-grown P3HT/FeCl₃ (FIG. 8). After 40 minutes, 45° C.-grown P3HT/FeCl₃ displays highly ordered nano-rod like features (FIG. 1C), while 85° C.-grown P3HT/FeCl₃ is porous (FIG. 1D). Modest electrical conductivities of 4.35±0.44 S/cm and 0.001±0.0004 S/cm are measured for 45° C. and 85° C.-grown P3HT/FeCl_{3,} respectively. The higher electrical conductivity of 45° C.-grown P3HT/FeCl₃ is hypothesized to originate from the longer conjugation length in quinoid structure²⁸ along the ordered chain. Both films display significant morphology changes after the de-doping process (FIGS. 1E-1F). The absence of residue confirms the high chemical purity (FIG. 9). Subsequent characterizations were performed on ˜100 nm thick dedoped films unless noted otherwise.

To investigate the thermal properties, thermal conductivities are measured by time-domain thermoreflectance (TDTR) technique^{29,30}. The oCVD sample is coated with ˜100 nm Al transducer via e-beam evaporation. The pump pulse heats up the sample surface, while the probe pulse detects the decay of surface temperature of Al. From the measured surface temperature decay, the effective thermal conductivity (k_{eff}) in the thickness (perpendicular to the substrate) direction can be obtained by fitting to a multilayer model derived from Fourier's law²⁸.

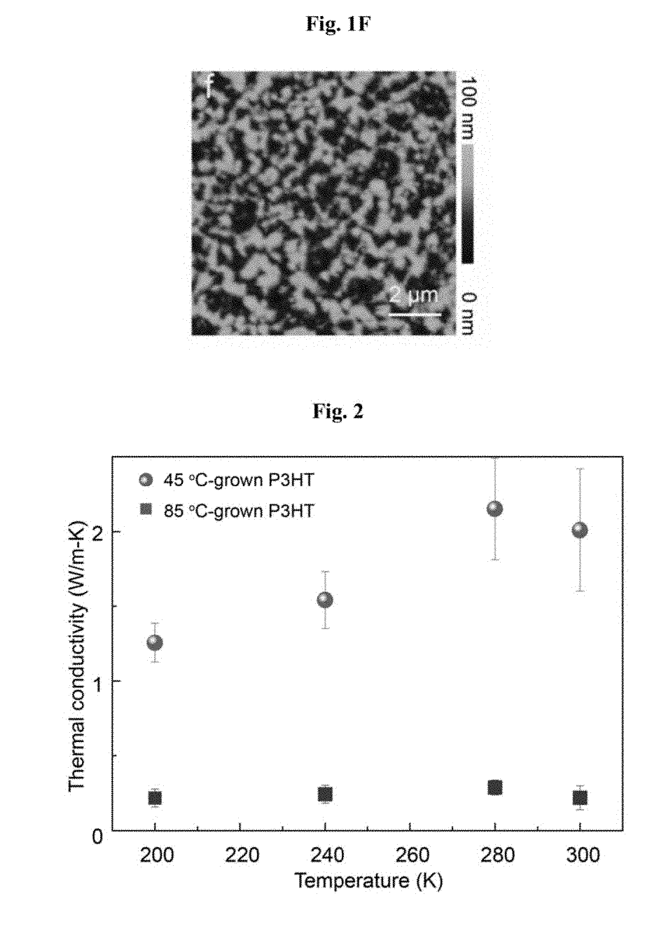

Remarkably, the 45° C.-grown P3HT film shows thermal conductivity 10 times higher than that of the 85° C.-grown film. The high thermal conductivity of the 45° C.-grown film also exhibits pronounced temperature-dependence, increasing from 1.26 W/m-K (200 K) to ˜2.15 W/m-K (280 K), and then reduces to 2.01 W/m-K (300 K) (FIG. 2). This trend generally reflects the polycrystalline nature, where at low temperatures phonon propagation is limited by the grain size and thermal conductivity increases with increasing phonon population, while at higher temperatures the intrinsic phonon scattering becomes dominant which leads to decreasing thermal conductivity as temperature is increased. As revealed by X-ray scattering analysis as discussed herein, the sample grown at 45° C. has both polycrystalline and amorphous region. Thus, in some embodiments the present thin films may be amorphous. In some embodiments the present thin films may be polycrystalline. In certain embodiments the present thin films may have a mixture of amorphous and polycrystalline regions. The observed temperature dependence of the thermal conductivity indicates that the structure of the molecular chains must be organized in a way that certain regions favor high order that resemble crystalline (or well-organized) grains (facilitated by the quinoid structure during the oCVD process), while the interconnections between them are more amorphous and behave like interfaces that more strongly scatter the heat transport as in polycrystalline samples.

Even though with the amorphous phase, the 45° C.-grown P3HT thermal conductivity perpendicular to the interface is 10 times higher than the common polymers¹¹. This could originate from the quinoid structure (FIG. 1 and FIG. 6D) with suppressed chain distortion during the chain growth process. The extended and relatively ordered distributed conjugated backbone are thus eventually achieved (FIG. 1B) instead of the coiled and entangled chains in common polymers (FIG. 7). The extended backbones with less distortions and entanglements facilitate the efficient phonon transport along the backbone.

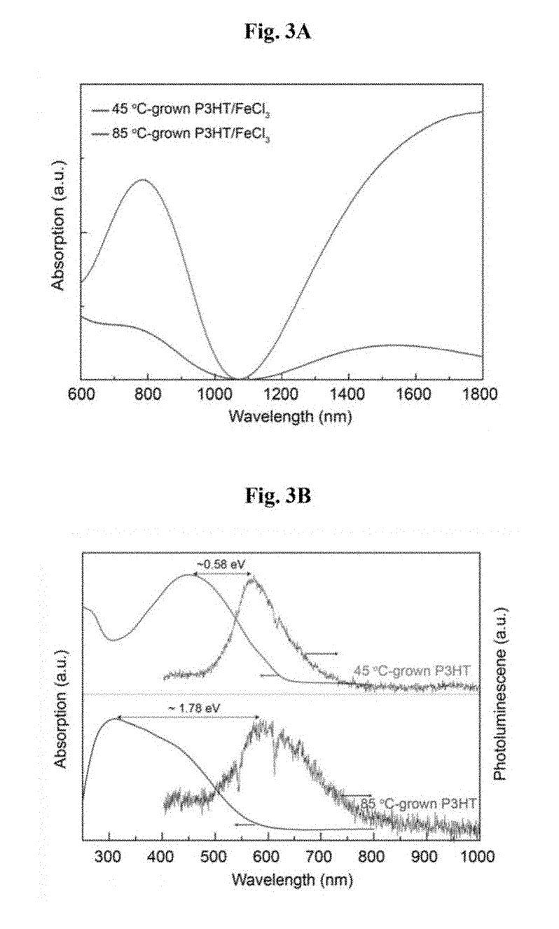

To confirm the presence of the quinoid structure, UV-vis-NIR spectra of 45° C. and 85° C.-grown P3HT/FeCl₃ is performed (FIG. 3A). Typical absorption bands of (bi)polaron are clearly observed at 600-900 nm and 1800 nm, which confirmed that (bi)polaron are present²⁷. It can thus be concluded that quinoid structure are present in the chain-growth process, which suppress the chain distortions. Comparing with 45° C.-grown P3HT/FeCl₃, the polaron and bipolar peaks are blue-shifted for the 85° C.-grown P3HT/FeCl₃, and such blue-shift may be an effect of more irregular polymer or shorter polymer length²⁷.

As the dynamics of thermal transport in polymer is a complex phenomenon that is affected by many factors including polymer chain structure and microstructure morphology, to explore the structure-thermal property relationship, first the conjugation length of the P3HT molecules and the degree of ordering in P3HT thin films (FIG. 1A (middle)) was examined by UV-Vis optical absorption spectroscopy³². Normalized UV-Vis absorption spectra of 45° C. and 85° C.-grown P3HT show maximum absorption (λmax) at ˜451 nm and 311 nm, respectively (FIG. 3B). This λₘₐₓ is assigned to the π-π* transition³³, and λₘₐₓ shifts towards longer wavelengths suggests that the longer conjugation length and more coplanar thiophene rings³⁴, which accords with its higher electrical conductivity in 45° C.-grown P3HT. Longer conjugation length can improve intrachain thermal transport^{35,33}. While π-extended coplanar backbones enable self-assemblies assemblies of regioregular sections to crystalline form, which is confirmed later by X-ray scattering analysis. Such ordered self-assemblies (FIG. 1B (middle)) connected by the extended chains critically contribute to high thermal conductivity in 45° C.-grown P3HT film.

To further investigate thermal conductivity affected by regiorandom backbone (FIG. 6C), photoluminescence spectroscopy was performed using laser excitation at 365 nm (FIG. 3B). The maximum emission wavelengths for 45° C. and 85° C.-grown P3HT are about the same (˜580 nm). Stokes shifts for 45° C. and 85° C.-grown P3HT are ˜0.58 eV and ˜1.78 eV, respectively. The Stokes shift of the emission spectra compared to absorption spectra indicates atomic relaxation upon excitation^{27,36}. When electrons are excited into higher level states via photo-absorption, the local polymer conformation adopts a more regular structure to stabilize the excited state, which is then followed by the red-shifted emission²⁷. The smaller Stokes shift observed in 45° C.-grown P3HT sample, therefore, suggests its ground state is in a more regioregular conformation and has less regiorandom structures (FIG. 6C), which is consistent with its higher thermal conductivity compared with the 85° C.-grown P3HT. The 85° C.-grown chains have more regiorandom structures, leading to amorphous thin-film growth, which is further confirmed by the later X-ray scattering characterizations. The disordered morphology of regiorandom chain not only results in smaller thermal conductivity along the chain, but also leads to larger separation and poor heat transfer between chains.

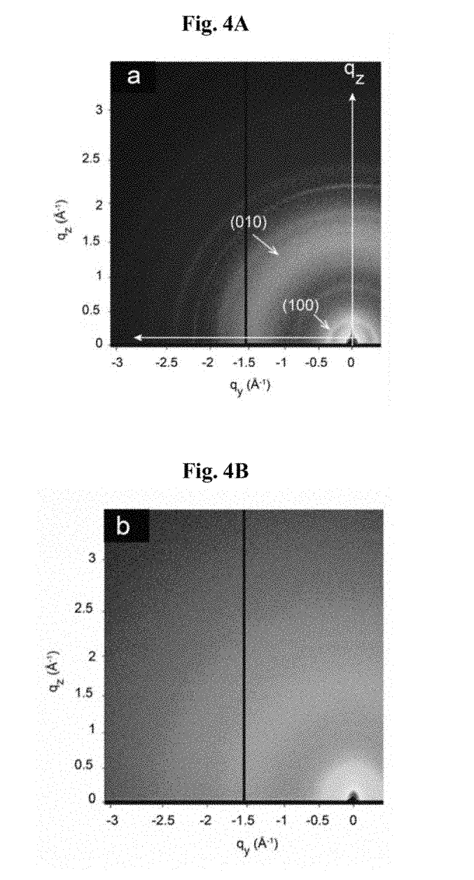

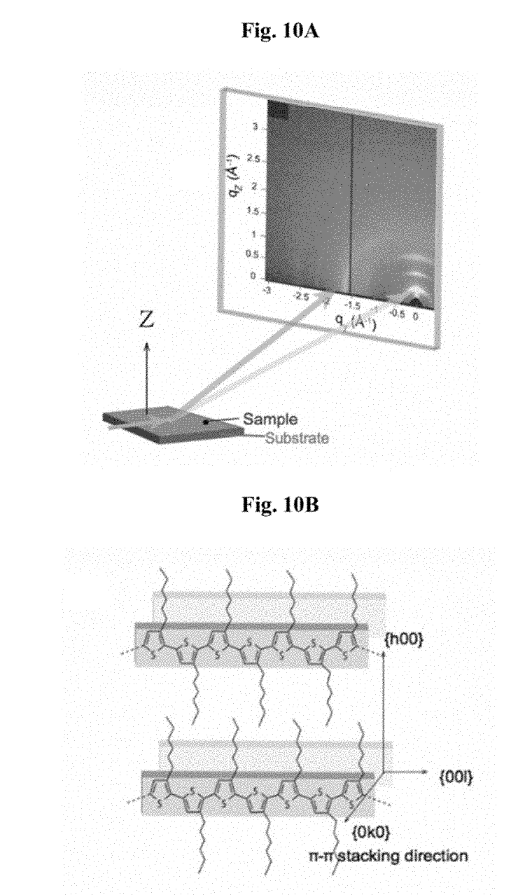

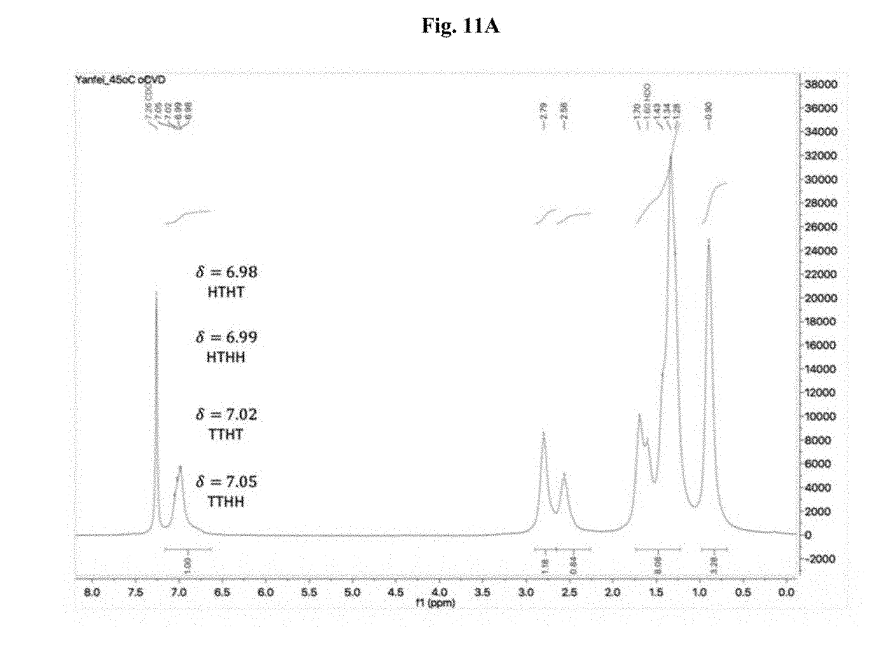

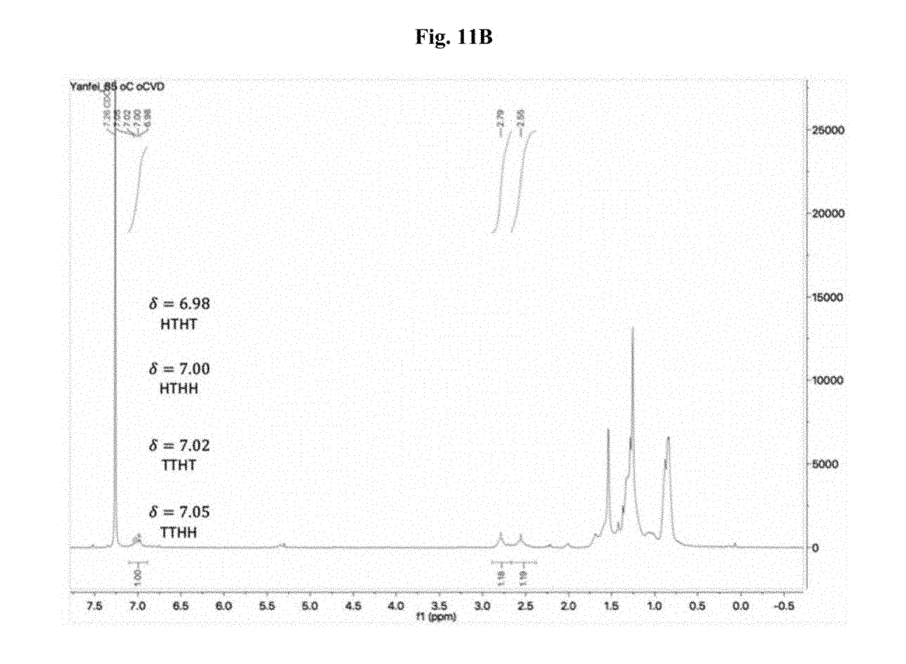

To further explain the observed temperature-dependence of the thermal conductivity, synchrotron grazing-incidence wide-angle x-ray scattering (GIWAXS) was used to investigate the nanostructures, including crystalline lattice constants and orientation information by {h00} and {0k0} scatterings (FIG. 4 and FIG. 10). The GIWAXS pattern from the 45° C.-grown P3HT film shows powder-scattering-like rings (FIG. 4A), suggesting a polycrystalline structure of no preferred molecular orientations with respect to the structure. This is favorable for three-dimensional spatial uniformity of its thermal conductive characteristics. The {100} scatterings due to the lamella layer structure (q˜0.38 Å⁻¹), and the {010} scattering due to π-π interchain stacking (q˜1.6 Å⁻¹), are present in the 45° C.-grown P3HT film, confirming the regular intermolecular self-assemblies by π-π interactions (FIG. 4A). In contrast, neither powder rings nor the {010} scatterings are observed in 85° C.-grown P3HT film (FIG. 4B), suggesting a dominant disordered structure, which agrees with the structural characterization (FIG. 11). As π-π stacking interaction is approximately 10-100 times stronger than vdW forces,²¹ thus, the observed π-π interactions along the {010} direction are expect to enable the efficient thermal transport between chains. The diffuse scatterings in FIGS. 4A-4B suggest that both 45° C. and 85° C.-grown P3HT contain a disordered phase.

Based the structural characterization and the prediction that individual polythiophene molecular chain has high thermal conductivity²⁰, one can interpret the experimentally measured high thermal conductivity of 45° C. grown P3HT in FIG. 2 as follows. Polycrystalline grains formed by regioregular P3HT are surrounded by amorphous regions. The amorphous regions have higher thermal resistance, which leads to typical temperature dependence in polycrystalline materials³⁷, first increasing with temperature due to the size effect that limits the thermal conductivity of the crystalline region. At higher temperatures, the thermal resistance of the amorphous region is reduced and phonon-phonon scattering in the crystalline region starts to limit the thermal conductivity, leading to a decreasing trend of thermal conductivity with increasing temperature.

In summary, the present disclosure provides near-room-temperature thermal conductivity of 2.2 W/m-K in the described thin films, which is 10 times higher than the conventional polymer films. In contrast with conventional efforts to enhance thermal conductivity by post-processing fabrication, such as mechanically stretching existing polymers or mixing available polymers, oCVD allows us to control both intermolecular and intramolecular structure at the molecular level during the polymerization process. Thermal and structural characterizations reveal that the strong conjugated double bonds along the rigid polymer chains in conjunction with the π-π stacking interactions between chains are at the heart of the substantially enhanced thermal transport. The damage-free nature and conformal growth inherent to the oCVD process allow for the formation of quality thin films with ideal thermal conductive properties on various substrates, demonstrating its versatility and near-universal applicability. Together with the wide range of material choice and scalability of the oCVD process, the benefits discussed herein open up a new avenue towards fabrication of lightweight and flexible polymeric heat conductors for thermal management applications.

### EXEMPLIFICATION

oCVD Experiment

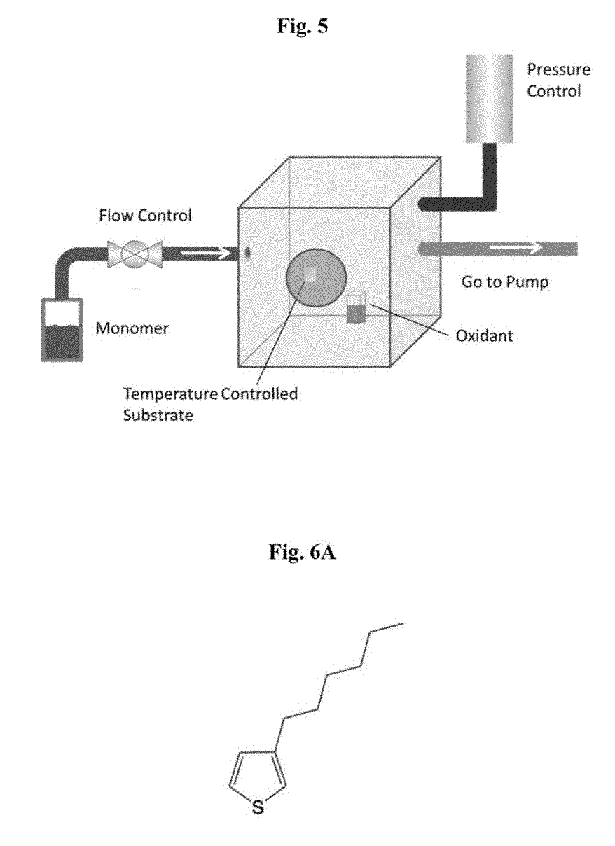

The process was conducted in a custom-built reactor reported in previous literature (FIG. 5)²⁵.

### Substrate Preparation

The oCVD P3HT samples were grown on sapphire, glass, and Si(100) substrate with a native silicon oxide layer. In order to enhance the adhesion of P3HT on silicon substrates, the silane grafting technique was applied²²: silicon substrates with the native silicon oxide layer were treated with oxygen plasma (29.6 W, 30 min) and then exposed to trichlorovinylsilane (TCVS-C₂H₃SiCl₃) while being heated to ˜75° C. to form the vinyl terminated surface for further P3HT linking.

### Equipment Setup

oCVD is a one-step process where the monomer and the oxidant are introduced simultaneously in the vapor phase in a vacuum chamber (FIG. 5). The process was conducted in a custom-built reactor reported in previous literature^{22,25,38,39}. The chamber was cubic with inner side length of 30 cm. The oxidant, FeCl₃(>97%, anhydrous, SigmaAldrich), was heated with a crucible in a heating furnace (LUXEL RADAK 1), placed on the back of the reactor inside the chamber. The substrate was placed on the front glass window of the reactor chamber. The distance between the substrate and the oxidant crucible is ˜30 cm. The temperature of the substrate was monitored with a thermocouple placed near the substrate inside the chamber, and controlled with cryogenic gel packet placed on the outer side of the glass window. The monomer, 3-hexylthiophene (≥99%, SigmaAldrich), was introduced with a heated glass jar (MDC Vaccum Products, LLC.) and through a heated tube. Both of the jar and tube are connected to the chamber from outside. The flowrate of the monomer was controlled by a needle valve (SS-4BMW-VCR, Swagelok). And the flowrate of the FeCl₃ was controlled by a hot tungsten wire.

### Experimental Conditions

During the oCVD growth, the pressure of the chamber was controlled at 4 mTorr. The monomer, 3-hexylthiophene, was heated at 140° C., and the oxidant, FeCl₃, was heated from 100° C. to ˜160° C. at a constant heating rate of 1.5° C./min. In order to control the oxidant amount, a glass tube with a heating tungsten wire (heated with ˜2.3 A×2.3 V) was added on top of the crucible to trap the excessive oxidant. The flow rate of the monomer was controlled at ˜1.2 sccm with opening the Swagelok needle valve for 4 turns, and the deposition time was ˜40 min. The outer wall of the reactor chamber was heated constantly to 200° C. in order to avoid unnecessary monomer adsorption. After the deposition, the film was rinsed with pure methanol at room temperature for 1 min in order to remove the residue oxidant and to fully dedope. After the rinsing step, the film was dried with blow of compressed air immediately.

### Characterization

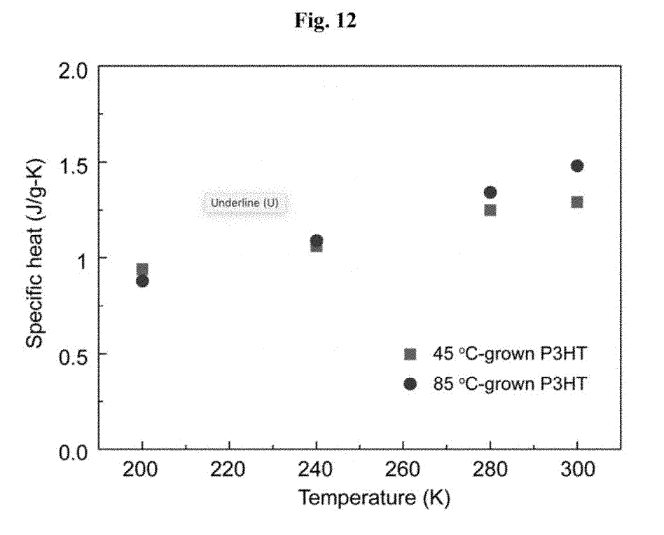

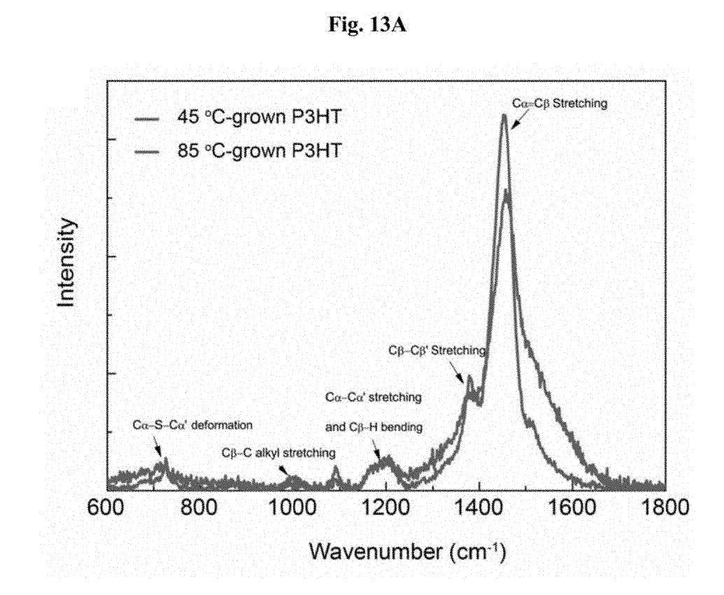

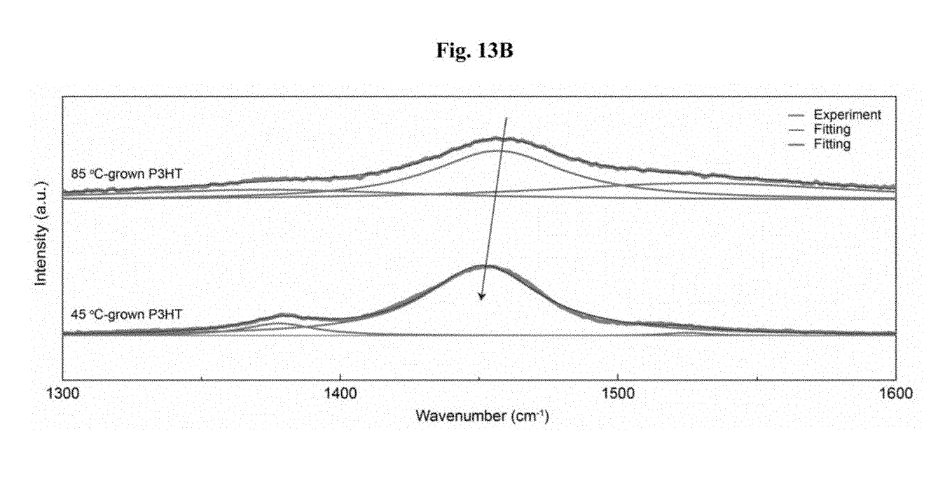

The molecular weight of the subject polymers was determined by gel permeation chromatography (Table 1, below), 45° C. and 85° C.-grown P3HT are eluted with tetrahydrofuran at 1.0 mL/min and measured relative to a polystyrene calibration curve. The glass transition temperature and specific heat are analyzed by differential scanning calorimetry measurement (DSC, FIG. 12). The ordered structure is further characterized by Raman spectroscopy (FIG. 13).

TABLE 1
Molecular Weights and Moeculr Weight Distribution

| | Mn | Mw | Distribution |
|---|---|---|---|
| 45° C.-grown P3HT | 7655 | 16650 | 2.17 |
| 85° C.-grown P3HT | 3520 | 5000 | 1.42 |

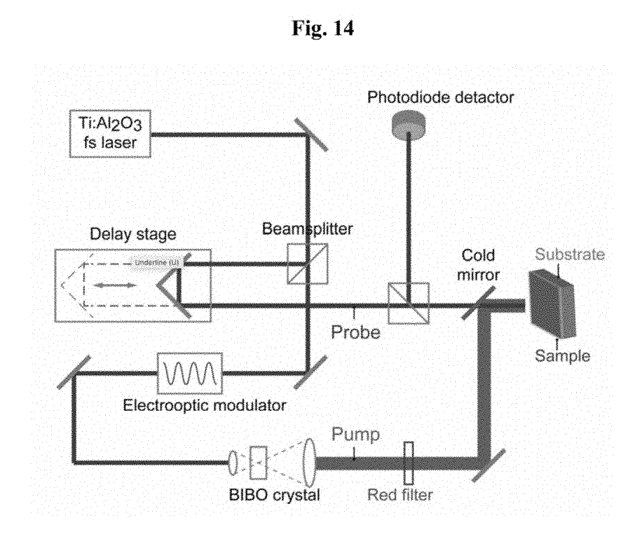

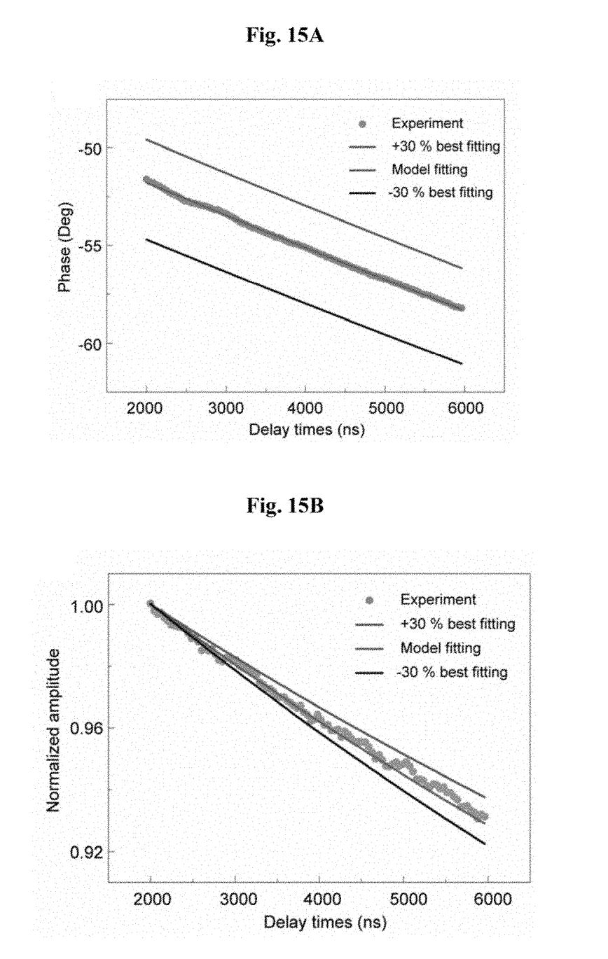

Ultraviolet-visible spectroscopy measurement: UV-Vis absorption was investigated by the Cary Series UV-Vis-NIR spectrophotometer (Agilent Technologies).
Photoluminescence spectroscopy: Samples deposited on glass slides were excited by a 365 nm, fiber-coupled LED (Thorlabs) for photoluminescence measurements. Photoluminescence spectra were collected in air using an Avantes fiber-optic spectrometer with an integration time of 100 ms, and each spectrum was averaged over 10 scans.
Raman spectroscopy: Raman spectroscopy was collected on a HORIBA Labram HR Evolution spectrometer, laser wavelength was 532 nm.
Differential scanning calorimetry measurement: DSC measurements were performed at atmospheric pressure by using a TA DSC RCS1-3277 instruments. The calorimeter was calibrated with standard sapphire. The melting behavior of crystals was investigated through a heating scan with a heating rate of 5 K/min at N₂ atmosphere.
Synchrotron X-ray scattering measurement: Synchrotron GIWAXS measurements were carried out at beamline 8-ID-E of the Advanced Photon Source (APS), Argonne National Laboratory, USA. The wavelength λ of the X-ray beam was 1.15 Å (10.82 keV). All samples were mounted in a vacuum chamber to reduce air scattering background. An incident angle below the critical angle of the total reflection of the silicon substrate (˜0.165 degree) was used to enhance the scattering signals. A Pilatus 1M area detector mounted 228 mm downstream of the sample was used to collect all GIWAXS data.
Thermal conductivity measurement: Time-domain thermoreflectance method was employed to measure the thermal conductivity of the polymer film (FIG. 14)^{30,31}. A pump laser beam heated up the sample surface. As the heat propagated into the material, the surface temperature decreased. A delayed probe laser beam was then reflected from the sample into the detector. The reflectance of the probe beam changed with the surface temperature (governed by the thermoreflectance coefficient), and thus recorded the surface temperature decay as time. A thin film of aluminum (˜100 nm) was deposited onto the film for larger signal because aluminum has large thermoreflectance coefficient. Pump beam had a wavelength of 400 nm while the probe beam had a wavelength of 800 nm. The measured thermoreflectance signals were then fitted to a standard two-dimensional, 3-layer heat conduction model considering the aluminum (Al) transducer, the polymer film and the interface in-between. Details of the thermal modeling can be found in past work³⁰. Multiple pump modulation frequencies (3 MHz, 6 MHz and 9MHz) were used, and the thermal conductivity at a fixed temperature for a given sample was taken to be the average of different measurements (FIG. 15).

### CITED REFERENCES

1. Peplow, M. The plastics revolution: how chemists are pushing polymers to new limits. Nat. News 536, 266-268 (2016).
2. Sperling, L. h. Introduction to polymer science. (John Wiley & Sons, Inc., 2005).
3. Henry, A. Thermal transport in polymers. Annu. Rev. Heat Transf. 17, 485-520 (2014).
4. Choy, C. L. Thermal conductivity of polymers. Polymer 18, 984-1004 (1977).
5. Poulaert, B., Chielens, J. C., Vandenhende, C., Issi, J. P. & Legras, R. Thermal conductivity of highly oriented polyethylene fibers. Polym Commun 31, 148-151 (1990).
6. Fujishiro, H., Ikebe, M., Kashima, T. & Yamanaka, A. Thermal conductivity and diffusivity of high-strength polymer fibers. Jpn. J. Appl. Phys. 36, 5633-5637 (1997).
7. Shen, S., Henry, A., Tong, J., Zheng, R. & Chen, G. Polyethylene nanofibres with very high thermal conductivities. Nat. Nanotechnol. 5, 251-255 (2010).
8. Wang, X., Ho, V., Segalman, R. A. & Cahill, D. G. Thermal conductivity of high-modulus polymer fibers. Macromolecules 46, 4937-4943 (2013).
9. Xu, Y. et al. Nanostructured Polymer Films with Metal-like Thermal Conductivity. ArXiv170806416 Cond-Mat (2017).
10. Singh, V. et al. High thermal conductivity of chain-oriented amorphous polythiophene. Nat. Nanotechnol. 9, 384-390 (2014).
11. Smith, M. K., Singh, V., Kalaitzidou, K. & Cola, B. A. Poly(3-hexylthiophene) Nanotube Array Surfaces with Tunable Wetting and Contact Thermal Energy Transport. ACS Nano 9, 1080-1088 (2015).
12. Roy, A. et al. Thermal Conductance of Poly(3-methylthiophene) Brushes. ACS Appl. Mater. Interfaces 8, 25578-25585 (2016).
13. Chen, H. et al. Thermal conductivity of polymer-based composites: fundamentals and applications. Prog. Polym. Sci. 59, 41-85 (2016).
14. Xie, X. et al. Thermal conductivity, heat capacity, and elastic constants of water-soluble polymers and polymer blends. Macromolecules 49, 972-978 (2016).
15. Kim, G. et al. High thermal conductivity in amorphous polymer blends by engineered interchain interactions. Nat. Mater. 14, 295-300 (2015).
16. Mu, L. et al. Molecular Origin of Efficient Phonon Transfer in Modulated Polymer Blends: Effect of Hydrogen Bonding on Polymer Coil Size and Assembled Microstructure. J. Phys. Chem. C 121, 14204-14212 (2017).
17. Shanker, A. et al. High thermal conductivity in electrostatically engineered amorphous polymers. Sci. Adv. 3, e1700342 (2017).
18. Ouellette, R. J. & Rawn, D. J. Organic Chemistry Structure, Mechanism, and Synthesis.
19. Balandin, A. A. Thermal properties of graphene and nanostructured carbon materials. Nat. Mater. 10, 569-581 (2011).
20. Zhang, T., Wu, X. & Luo, T. Polymer Nanofibers with Outstanding Thermal Conductivity and Thermal Stability: Fundamental Linkage between Molecular Characteristics and Macroscopic Thermal Properties. J. Phys. Chem. C 118, 21148-21159 (2014).
21. Frieden, E. Non-covalent interactions: Key to biological flexibility and specificity. J. Chem. Educ. 52, 754 (1975).
22. Ugur, A. et al. Low-Dimensional Conduction Mechanisms in Highly Conductive and Transparent Conjugated Polymers. Adv. Mater. 27, 4604-4610 (2015).
23. Wang, M. et al. CVD Polymers for Devices and Device Fabrication. Adv. Mater. 29, n/a-n/a (2017).
24. Coclite, A. M. et al. 25th Anniversary Article: CVD Polymers: A New Paradigm for Surface Modification and Device Fabrication. Adv. Mater. 25, 5392-5423 (2013).
25. Gleason, K. K. Wiley: CVD Polymers: Fabrication of Organic Surfaces and Devices-Karen K. Gleason. Available at: http://www.wiley.com/WileyCDA/WileyTitle/productCd-3527337997.html. (Accessed: 21 Jun. 2017)
26. Asatekin, A. et al. Designing polymer surfaces via vapor deposition. Mater. Today 13, 26-33 (2010).
27. Semiconducting and Metallic Polymers (Oxford Graduate Texts) by Heeger, Alan J.; Sariciftci, Niyazi Serdar; Namdas, Ebinazar B.: Oxford University Press 2010-09-25 9780198528647 Hardcover, 1.-Bellwetherbooks. Available at: https://www.abebooks.com/Semiconducting-Metallic-Polymers-Oxford-Graduate-Texts/22404020880/bd. (Accessed: 1 Jul. 2017)
28. Heeger, A. J. Semiconducting and metallic polymers: the fourth generation of polymeric materials (Nobel Lecture). Angew. Chem. Int. Ed. 40, 2591-2611 (2001).
29. Cahill, D. G. Analysis of heat flow in layered structures for time-domain thermoreflectance. Rev. Sci. Instrum. 75, 5119-5122 (2004).
30. Schmidt, A. J., Chen, X. & Chen, G. Pulse accumulation, radial heat conduction, and anisotropic thermal conductivity in pump-probe transient thermoreflectance. Rev. Sci. Instrum. 79, 114902 (2008).
31. Cahill, D. G. et al. Nanoscale thermal transport. J. Appl. Phys. 93, 793-818 (2003).
32. Tsoi, W. C. et al. The Nature of In-Plane Skeleton Raman Modes of P3HT and Their Correlation to the Degree of Molecular Order in P3HT:PCBM Blend Thin Films. J. Am. Chem. Soc. 133, 9834-9843 (2011).
33. Nejati, S. & Lau, K. K. S. Chemical Vapor Deposition Synthesis of Tunable Unsubstituted Polythiophene. Langmuir 27, 15223-15229 (2011).
34. Igor F. Perepichka, Dmitrii F. Perepichka. Handbook of Thiophene-Based Materials: Applications in Organic Electronics and Photonics. DOI: 10.1002/9780470745533,
35. Brédas, J. L. Relationship between band gap and bond length alternation in organic conjugated polymers. J. Chem. Phys. 82, 3808-3811 (1985).
36. Busby, E. et al. Excited-State Self-Trapping and Ground-State Relaxation Dynamics in Poly(3-hexylthiophene) Resolved with Broadband Pump-Dump-Probe Spectroscopy. J. Phys. Chem. Lett. 2, 2764-2769 (2011).
37. Chen, G. Nanoscale Energy Transport and Conversion: A Parallel Treatment of Electrons, Molecules, Phonons, and Photons. (Oxford University Press, 2005).
38. Tenhaeff, W. E. & Gleason, K. K. Initiated and Oxidative Chemical Vapor Deposition of Polymeric Thin Films: iCVD and oCVD. Adv. Funct. Mater. 18, 979-992 (2008).
39. Howden, R. M., McVay, E. D. & Gleason, K. K. oCVD poly(3,4-ethylenedioxythiophene) conductivity and lifetime enhancement via acid rinse dopant exchange. J. Mater. Chem. A 1, 1334-1340 (2012).
40. Pappenfus, T. M. et al. Regiochemistry of Poly(3-hexylthiophene): Synthesis and Investigation of a Conducting Polymer. J. Chem. Educ. 87, 522-525 (2010).

### INCORPORATION BY REFERENCE

All US and PCT patent application publications and US patents mentioned herein are hereby incorporated by reference in their entirety as if each publication or patent was specifically and individually indicated to be incorporated by reference.

### EQUIVALENTS

While specific embodiments of the subject invention have been discussed, the above specification is illustrative and not restrictive. Many variations of the invention will become apparent to those skilled in the art upon review of this specification and the claims below. The full scope of the invention should be determined by reference to the claims, along with their full scope of equivalents, and the specification, along with such variations.

1. A thin film comprising a plurality of polymer chains, wherein:
a. each polymer chain is a polymer of at least one monomer;
b. each polymer chain comprises a quinoid-type region, wherein the quinoid-type region comprises an extended array of conjugated π-bonds, and said quinoid-type region has a rigid, planar molecular configuration;
c. said quinoid-type regions of the polymer chains interact electronically;
d. said thin film comprises at least one area wherein said polymer chains are well-ordered;
e. said thin film comprises extended polymer chains; and
f. said thin film exhibits a thermal conductivity (κ) of at least about 1 W/mK at 296 K.

2. The thin film of claim 1, wherein said at least one monomer is an unsubstituted or substituted quinone, pyridine, pyridone, pyrimidine, pyrimidone, thiophene, thiophenone, pyrrole, furan, or a combination of any of them.

3. The thin film of claim 2, wherein the unsubstituted or substituted quinone, pyridine, pyridone, pyrimidine, pyrimidone, thiophene, thiophenone, pyrrole, furan, or combination thereof is at least partially oxidized.

4. The thin film of claim 2, where said at least one monomer is a pyrrole or a thiophene.

5. (canceled)

6. The thin film of claim 4, where said at least one monomer is a thiophene.

7. The thin film of claim 6, where said at least one monomer is an alkylthiophene.

8. The thin film of claim 7, wherein said alkylthiophene is a 3-alkylthiophene.

9. The thin film of claim 8, wherein said 3-alkylthiophene is 3-hexylthiophene.

10. The thin film of claim 1, wherein the thin film exhibits a thermal conductivity (κ) of at least about 1.5 W/mK at 296 K.

11. (canceled)

12. (canceled)

13. The thin film of claim 1, wherein said at least one area exhibits polycrystalline characteristics.

14. (canceled)

15. (canceled)

16. The thin film of claim 1, wherein said thin film has a thickness of about 100 nm to about 210 nm.

17. (canceled)

18. (canceled)

19. The thin film of claim 1, further comprising an oxidant.

20. The thin film of claim 19, wherein said oxidant is a metal halide.

21. The thin film of claim 20, wherein said metal halide is FeCl₃.

22. The thin film of claim 1, wherein said thin film exhibits a thermal conductivity (κ) of at least about 1 W/mK from about 220 K to about 473 K.

23-26. (canceled)

27. A semiconductor device, comprising the thin film of claim 1.

28. A consumer electronics device, comprising the thin film of claim 1.

29. A method of preparing a thin film of claim 1 on a surface of a substrate, comprising the steps of:
a. depositing at least one monomer on said surface, thereby forming a coated surface;
b. depositing an oxidant on said coated surface; and
c. allowing said at least one monomer and said oxidant to react, thereby forming said thin film on said surface of said substrate.

30-32. (canceled)
